(19) United States
(12) Patent Application Publication
(10) Pub. No.: US 2004/0113823 A1
(43) Pub. Date: Jun. 17, 2004

(54) Synchronization of parallel data streams from a serial source

(76) Inventors: Ren-Yuan Huang, Irvine, CA (US); Yi-Ren Hwang, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 10/248,050

(22) Filed: Dec. 13, 2002

(51) Int. Cl. H03M 9/00

(52) U.S. Cl. 341/100

(57) ABSTRACT

Output data lines generate data according to a corresponding sampling clock. For each output data line, a latch cascade is provided. Each latch cascade has an input end and an output end, and includes at least one latch. Data presented at the input end of a latch cascade cascades through the latch cascade and is presented at the output end of the latch cascade. The output end of each latch cascade is a final latch in the latch cascade. Each output data line is respectively connected to the input end of one of the latch cascades. The final latch in each latch cascade is triggered by a common clock signal. Finally, for each latch cascade having two or more latches, a triggering clock triggers an initial latch in each latch cascade. The triggering clock is phase shifted after the sampling clock of the corresponding output data line. This corresponding output data line is connected to the initial latch.

### BACKGROUND OF INVENTION

1. Field of the Invention

The present invention relates to serial data streams. More specifically, the present invention discloses the synchronization of parallel data streams that are generated by the sampling of a single serial data stream.

2. Description of the Prior Art

Serial data transmissions can reach exceedingly high data transmission rates, for example over 1.5 Gigabits per second. Within data processing equipment, however, data is typically handled as bytes. Serial-to-parallel conversion circuits exist that convert a high frequency serial data stream (perhaps on the order of gigahertz) into a parallel stream of data at a lower frequency (perhaps on the order of megahertz).

Please refer to FIG. 1. FIG. 1 is a process block diagram of serial-to-parallel conversion. A serial bit stream 20 is provided, and is arbitrarily subdivided into n-bit blocks 22. In this case, n is four, so that a 1-to-4 serial-to-parallel conversion is being performed. The bit stream 20 is fed into a 1-to-4 conversion circuit 24, which generates a corresponding 4-bit parallel stream 26 from the serial stream 20. Please refer to FIG. 2 in conjunction with FIG. 1. FIG. 2 is a block diagram of a prior art serial-to-parallel conversion circuit 10 to perform the conversion depicted in FIG. 1. High frequency serial data, corresponding to item 20 in FIG. 2, is provided on serial data lines D⁺ and D⁻. D⁺ and D⁻ are logical inversions of each other. That is, when D⁺ is high D⁻ is low, and vice versa. Such inversion pairing of high speed serial streams is quite common, and for the purposes of the present invention only one side of the pair need be considered, such as the D⁺ serial line. The high speed serial data lines D⁺ and D⁻ feed into a plurality of sampler blocks 12a-12d. The example circuit 10 performs a 1-to-4 serial to parallel conversion, and so four sampler blocks 12a-12d are present. In general, a 1-to-n conversion will have n sampler blocks, and is easily applied to the following discussion.

Please refer to FIG. 3 with reference to FIGS. 1 and 2. FIG. 3 is a signal timing diagram for data lines depicted in FIG. 2. Each sampler block 12a-12d has a corresponding sampling clock signal CLK1-CLK4. Each sampling clock signal CLK1-CLK4 has a sampling frequency that is ¼ (i.e., 1/n^{th}) that of the sampling frequency for the serial data lines D⁺ and D⁻. The sampling clocks signals CLK1-CLK4 are also phase shifted with respect to each other by one period of the serial data sampling frequency. In this manner, the samplers 12a-12d together sample four consecutive bits from the serial data lines D⁺ and D⁻, with each sampler 12a-12d sampling every fourth bit. For example, sampler 12a samples the first bit 1A, 2A, 3A, 4A, 5A and 6A in each bit block 22, and so may be termed the first sampler 12a. Sampler 12b samples the second bit 1B, 2B, 3B, 4B, 5B and 6B in each bit block 22, and so is termed the second sampler 12b. Similarly, sampler 12c is termed the third sampler 12c (responsible for sampling bits 1C, 2C, 3C, 4C, 5C and 6C), and sampler 12d is termed the fourth sampler 12d (responsible for sampling bits 1D, 2D, 3D, 4D, 5D and 6D). A sampler 12a-12d can be said to be ahead of or behind another sampler 12a-12d based upon the phase shift of its respective sampling clock signal CLK1-CLK4. For example, the first sampler 12a is immediately subsequent the fourth sampler 12d, and immediately prior to the second sampler 12b. The second sampler 12b is immediately subsequent to the first sampler 12a, and immediately prior to the third sampler 12c, etc.

In FIG. 3, it is assumed that sampling occurs on the rising edge of the sampling clock signals CLK1-CLK4. Because of the phase shift within their sampling clock signals CLK1-CLK4, the respective outputs Out1-Out4 of the samplers 12a-12d are not synchronized. To be useful to subsequent logic, the output data lines Out1-Out4 must be synchronized with each other. A synchronizing block 14 is provided for this purpose, and generates as output data lines OutA-OutD that are synchronized versions of the output data lines Out1-Out4. FIG. 4 illustrates the synchronized outputs OutA-OutD obtained from the unsynchronized data lines Out1-Out4. The synchronized outputs OutA-OutD are synchronized with a synchronizing clock signal CLK_S.

In the prior art, the most common method used to implement the synchronizing block 14 is to use one of the sampling clocks CLK1-CLK4 to latch data present on the unsynchronized data lines Out1-Out4. For example, sampling line CLK4 may be used as the synchronizing clock signal CLK_S to latch the data present on Out1-Out4. However, doing so leads to racing issues, as any of the sampling clocks CLK1-CLK4 corresponds to a potential data transition of one of the corresponding output lines Out1-Out4. This can lead to setup or hold time violations of the latch within the synchronizing block 14.

### SUMMARY OF INVENTION

It is therefore a primary objective of this invention to provide a synchronization circuit in serial-to-parallel data conversion circuit that avoids racing issues, and which ensures properly synchronized output data.

Briefly summarized, the preferred embodiment of the present invention discloses a method for synchronizing a plurality of output data lines. Each output data line generates data according to a corresponding sampling clock. Latch cascades are provided for the output data lines. Each latch cascade has an input end and an output end, and includes at least one latch. Data presented at the input end of a latch cascade cascades through the latch cascade and is presented at the output end of the latch cascade. The output end of each latch cascade is a final latch in the latch cascade. Each output data line is respectively connected to the input end of one of the latch cascades. The final latch in each latch cascade is triggered by a common clock signal. Finally, for each latch cascade having two or more latches, an initial latch in each latch cascade is triggered by a triggering clock that is phase shifted after the sampling clock of the corresponding output data line. This corresponding output data line is connected to the initial latch.

It is an advantage of the present invention that each latch in the latch cascades is provided an ample amount of time for setup and hold conditions, and hence racing issues are avoided.

These and other objectives of the present invention will no doubt become obvious to those of ordinary skill in the art after reading the following detailed description of the preferred embodiment, which is illustrated in the various figures and drawings.

### BRIEF DESCRIPTION OF DRAWINGS

FIG. 1 is a process block diagram of serial-to-parallel conversion.

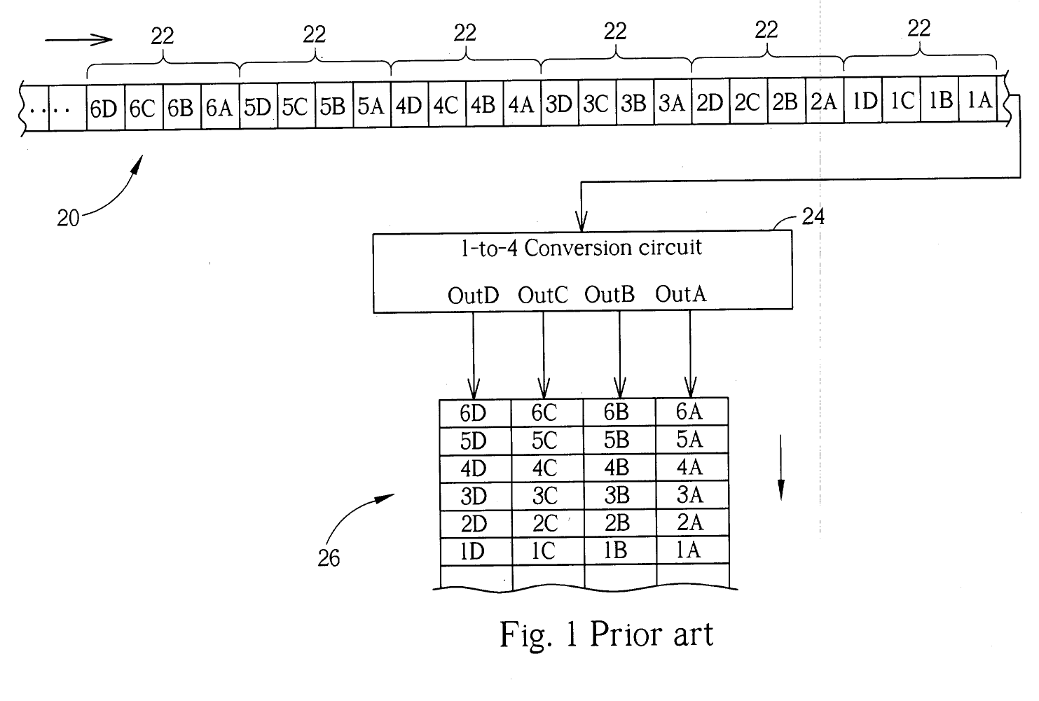

FIG. 2 is a block diagram of a prior art serial-to-parallel conversion circuit according to the prior art.

FIG. 3 is a signal timing diagram for data lines depicted in FIG. 1.

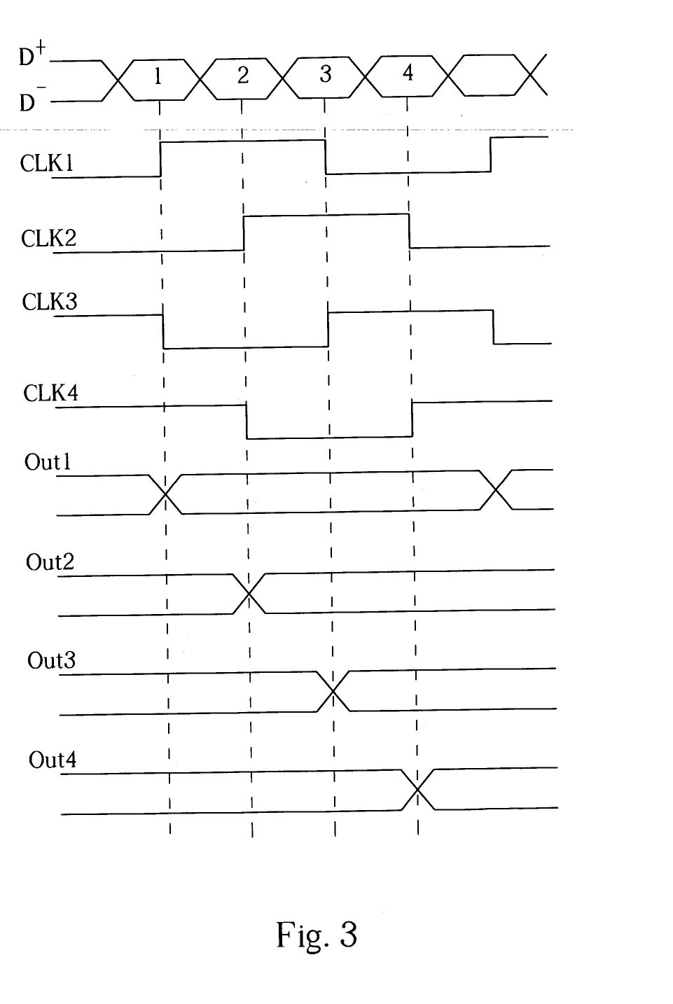

FIG. 4 is a timing diagram illustrating synchronized outputs obtained from unsynchronized data lines depicted in FIGS. 1 and 2.

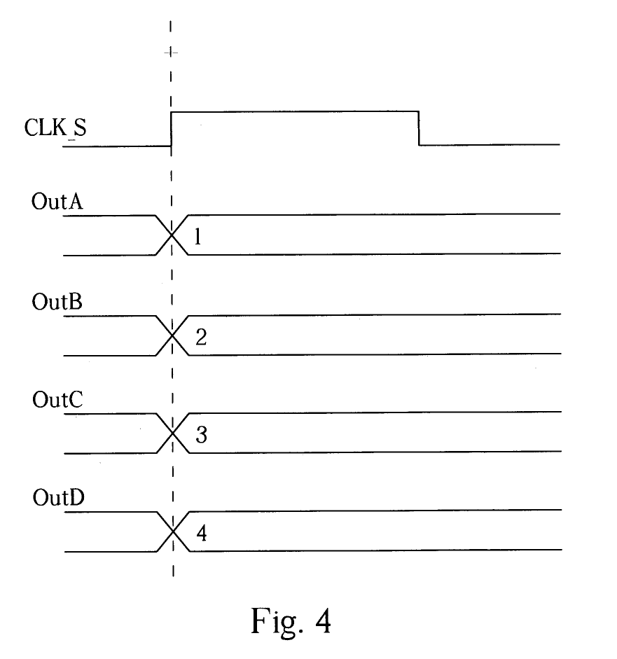

FIG. 5 is a block diagram of a 1-to-n serial-to-parallel converter that employs the method of the present invention.

FIG. 6 is a process block diagram of serial-to-parallel conversion as performed by the converter of FIG. 5.

FIG. 7 is a timing diagram of a latch cascade depicted in FIG. 5.

FIG. 8 is a process block diagram of serial-to-parallel conversion as performed by an alternative converter utilizing the present invention method.

FIG. 9 is a block diagram of a 1-to-n serial-to-parallel converter that performs the conversion depicted in FIG. 8.

FIG. 10 is a block diagram of a second embodiment synchronization block according to the present invention.

FIG. 11 is a timing diagram for the synchronization block of FIG. 10.

### DETAILED DESCRIPTION

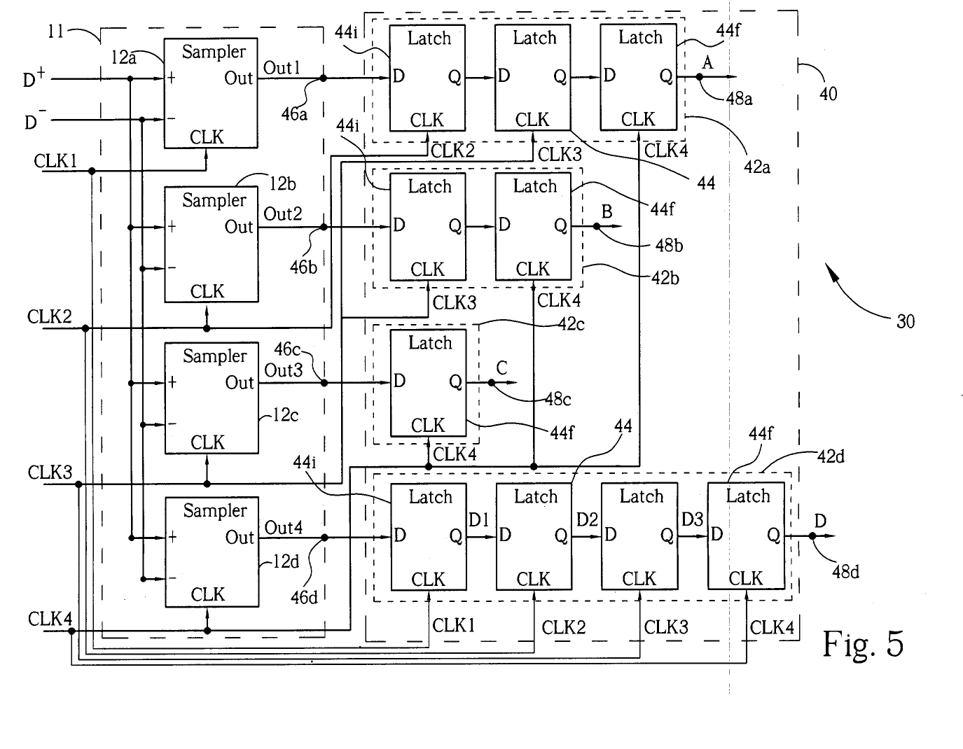

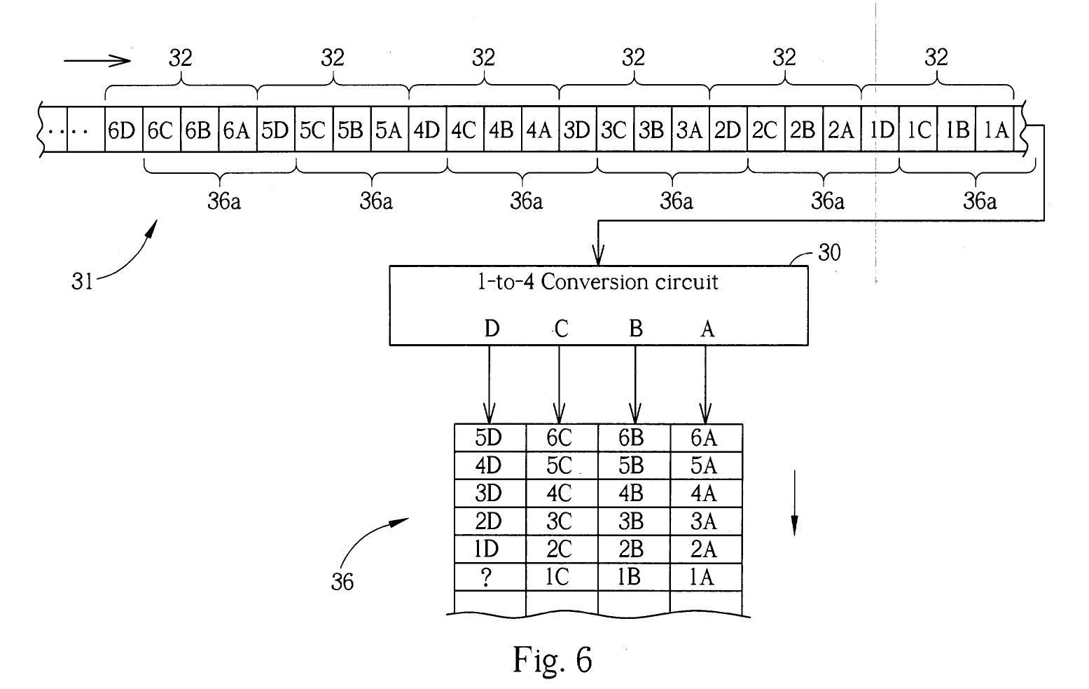

Please refer to FIGS. 5 and 6. FIG. 5 is a block diagram of a 1-to-n serial-to-parallel converter 30 that employs the method of the present invention. FIG. 6 is a process block diagram of serial-to-parallel conversion as performed by the converter 30. The serial-to-parallel converter 30 is, by way of example, a 1-to-4 serial-to-parallel converter, so that “n” is four. It should be clear to one skilled in the art, however, that the present invention is intrinsically scalable, and the method for doing so should be easily understood after reading the following detailed description.

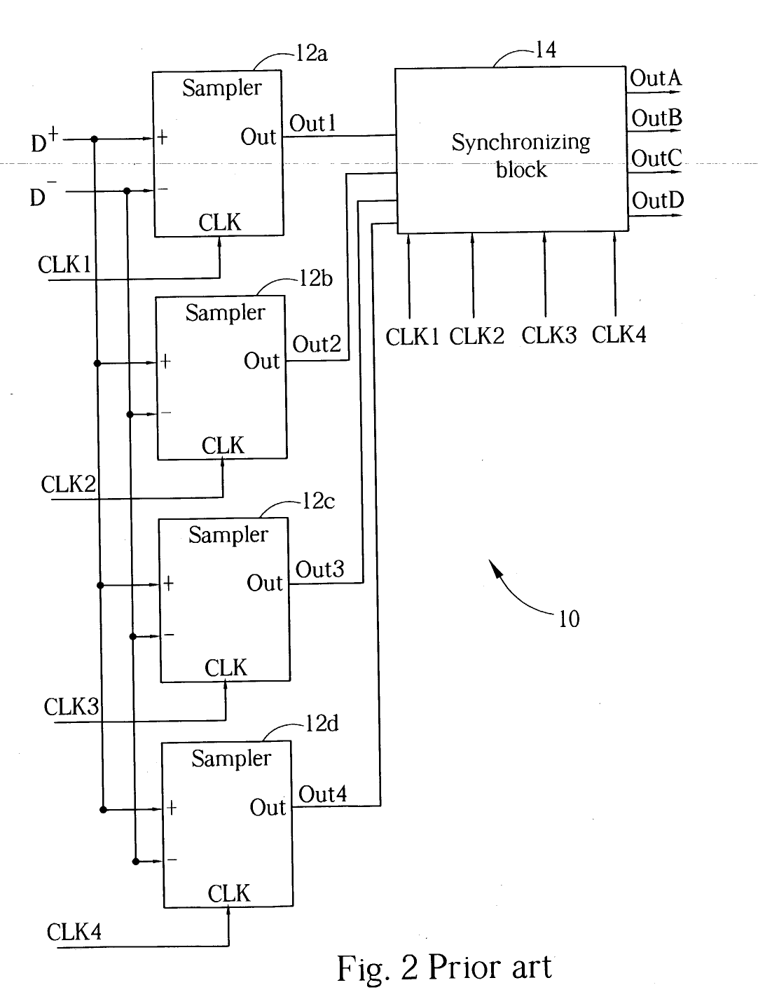

It is the purpose of the present invention to provide a synchronizing block 40 for synchronizing output data lines Out1-Out4 from a sampling block 11. Items in FIG. 5 that serve the same purpose as those of the prior art depicted in FIG. 2 are shown with the item numbers from FIG. 2. As the circuit 30 is a 1-to-4 serial-to-parallel conversion circuit, the sampling block 11 includes the four samplers 12a-12d, each with its respective sampling clock signal CLK1-CLK4. Each sampler 12a-12d has its corresponding data output line Out1-Out4, which respectively provide one bit from a bit block 32, as extracted from a stream of serial data 31 provided on serial data input lines D⁺ and D⁻. The output data lines Out1-Out4 are not synchronized, however, and it is the job of the synchronizing block 40 to provide synchronized data A-D in the form of a parallel bit stream 36 that corresponds to the data presented by the output data lines Out1-Out4.

To this end, the synchronizing block 40 includes four latch cascades 42a-42d, which are respectively connected to the output data lines Out1-Out4. Each latch cascade 42a-42d contains at least one latch 44, and each latch cascade 42a-42d has an input end 46a-46d and an output end 48a-48d. The latches 44 in each latch cascade 42a-42d are series connected together so that data presented at the input end 46a-46d cascades through the latch cascade 42a-42d and is eventually output at output end 48a-48d by a final latch 44f. The output Q of a final latch 44f serves as the output end 48a-48d of the corresponding latch cascade 42a-42d.

In a latch cascade 42a-42d, each latch 44 is triggered by a different trigger clock input signal CLK. That is, in the preferred embodiment, within the same latch cascade 42a-42d, no latch 44 shares the same trigger clock input signal CLK. However, every final latch 44f across the latch cascades 42a-42d utilizes the same common trigger clock input signal CLK, and because of this the outputs A-D are synchronized. In the preferred embodiment, the trigger clock input signals CLK are selectively connected to one of the sampling clock signal lines CLK1-CLK4, and hence the latches 44 trigger on the same clock edge that triggers the samplers 12a-12d. For example, if the samplers 12a-12d sample on the positive edge of the CLK1-CLK4 signals, then the latches 44 would similarly trigger on the positive edge of the clock signals CLK1-CLK4. The common trigger clock signal CLK for the final latches 44f is selected to be the sequentially latest sampling clock, which in this case is CLK4 (i.e., the sampling clock corresponding to the last bit 1D, 2D, 3D, etc., in a serial bit block 32). If the sampling clocks CLK1-CLK4 are not used as trigger clock signals CLK, then the common trigger clock signal CLK for the final latches 44f should be one which is phase shifted to be on or after the sequentially latest sampling clock signal (e.g., phase shifted to be on or after CLK4). It should be clear that making use of the sampling clock signals CLK1-CLK4 as the latch trigger clock signals CLK is for simplicity of design, which makes for a circuit that is easier to implement and use. However, it is certainly possible to provide separate latch trigger clock signals CLK, so long as their timing is consistent with that of the sampling clock signals CLK1-CLK4 in the manner detailed below.

For each latch cascade 42a, 42b, 42d having more than one latch 44, the timing of the trigger clock signals CLK is such that latches 44 closer to the input ports 46a, 46b, 46d trigger before latches closer to the output ports 48a, 48b, 48d. The latch cascades 42a, 42b, 42d, which have two or more latches 44, each have an initial latch 44i that accepts data from the respective output data line Out1, Out2, Out4. The initial latches 44i are triggered after the output data lines Out1, Out2, Out4 have presented their newest data. That is, the triggering edge for the clock signal CLK of an initial latch 44i should be phase shifted to be after the sampling edge of the sampling clock signal CLK1, CLK2, CLK4 for the corresponding sampler 12a, 12b, 12d. To this effect, each initial latch 44i is triggered by a sampling clock signal CLK2, CLK3, CLK1 that is immediately after the sampling clock signal CLK1, CLK2, CLK4 corresponding to the output data line Out1, Out2, Out4 that feeds into the initial latch 44i. For example, the initial latch 44i in the latch cascade 42a serves as the input port 46a, accepting data from the output data line Out1. The output data line Out1 generates data according to the sampling clock signal CLK1. Hence, the initial latch 44i in the latch cascade 42a should be triggered after the sampling edge of CLK1. Consequently, the sampling clock signal CLK2 is used to trigger the latch 44i in the latch cascade 42a. Similarly, initial latch 44i in the latch cascade 42b is triggered by sampling clock CLK3. Note that the sampling clock signal immediately after CLK4 is CLK1, and so initial latch 44i in the latch cascade 42d is triggered by the sampling clock signal CLK1.

Within each latch cascade 42a, 42b, 42d having more than one latch 44, latches 44 sandwiched between the initial latch 44i and the final latch 44f should trigger after the initial latch 44i, and before the final latch 44f. These sandwiched latches 44 should also trigger in their series order, with those closest to the initial latch 44i triggering before those closest to the final latch 44f. Such conditions clearly impose the phase format of the triggering clock signals CLK. With regards to the circuit 30, which exclusively uses the sampling clock signals CLK1-CLK4 as the triggering clock signals CLK, these conditions clearly indicate how the sandwiched latches 44 should have their trigger clock lines CLK electrically connected to one of the sample clock lines CLK2, CLK3. Note that CLK4 is reserved for the final latches 44f, and so is not available to sandwiched latches 44, or initial latches 44i. Determination of how many latches 44 should be in each latch cascade 42a-42d begins by first providing the final latch 44f with its associated common trigger clock signal, and then working backwards inserting latches 44 as a series chain that feeds into the final latch 44f until the initial latch 44i is inserted. The initial latch 44i, like the final latch 44f, is identified by its corresponding trigger clock signal CLK, the characteristics of which are described above.

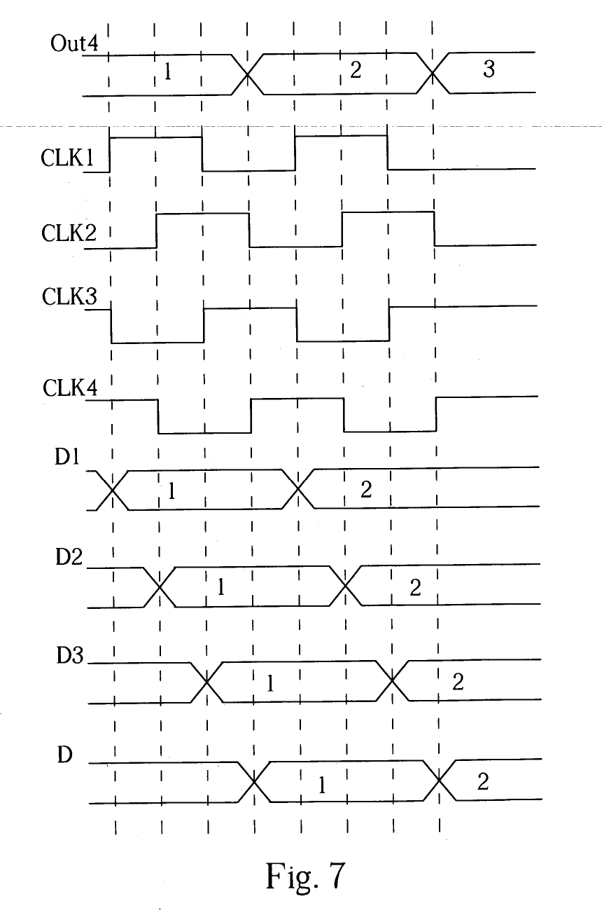

Please refer to FIG. 7 in conjunction with FIGS. 5 and 6. FIG. 7 is a timing diagram of latch cascade 42d. As can be seen in FIG. 7, data which is present on output line Out4 cascades through latch cascade 42d, propagating along between the latches 44 through lines D1, D2 and D3, until the data is finally presented as synchronized output D. Note that the synchronized output D, due to the propagation delays imposed by the latch cascade 42d, lags behind by the time of one complete bit block 32. Hence, although the serial stream 31 is sampled as blocks 32, the serial stream 31 is presented by the conversion circuit 30 as the streaming parallel blocks 36, which are the bit blocks 36a clocked out at ¼ the frequency of the serial stream 31.

It should be noted that it is a trivial matter to introduce additional latches 44 into each latch cascade 42a-42d so as to impose additional propagation delays. Such additional latches 44 are not considered part of the synchronization block 40, though, and are instead, for purposes of the present invention, considered as part of subsequent logic that is fed by the conversion circuit 30.

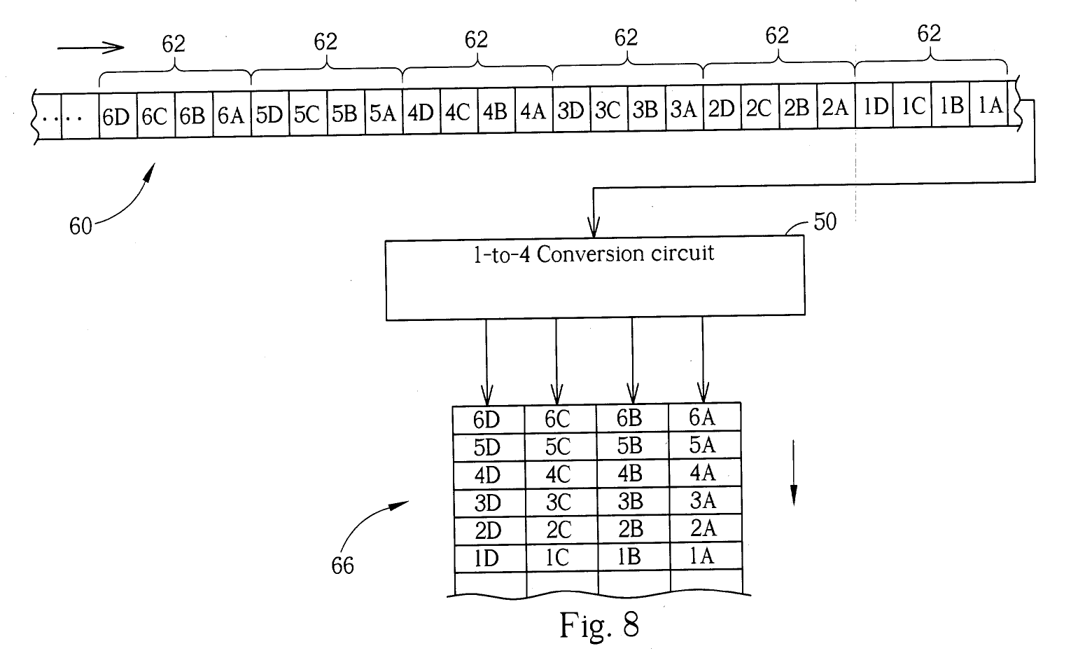

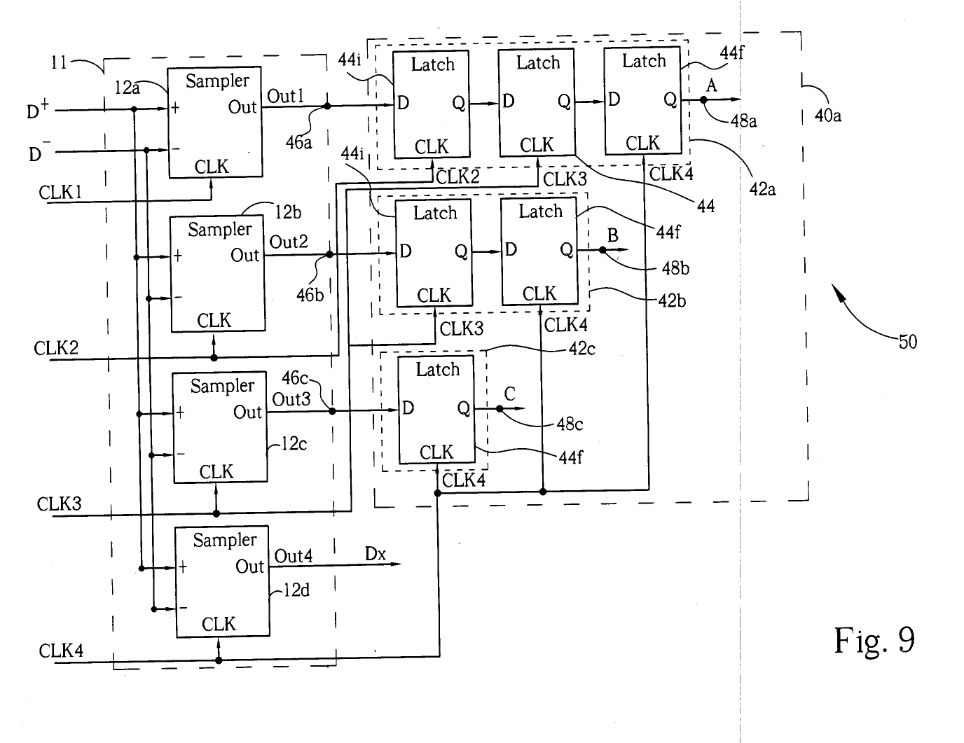

In the above embodiment, for n-bit bit blocks 32, the last bit in each bit block 32 is assigned to a sampler 12d having a latch cascade 42d with n latches 44. Subsequent samplers 12a-12c are assigned consecutively lesser number of latches 44 in their respective latch cascades 42a-42c, down to a single final latch 44f. Such an arrangement provides parallel output as depicted in FIG. 6. Please refer to FIGS. 8 and 9. FIG. 8 is a process block diagram of serial-to-parallel conversion as performed by an alternative converter 50 according to the present invention method. FIG. 9 is a block diagram of the 1-to-n serial-to-parallel converter 50 (with n=4) that performs the conversion depicted in FIG. 8. Note that in the general case of 1-to-n conversion, the converter according to the alternative embodiment of the present invention will have n samplers, and n−1 latch cascades, the latch cascades having from n−1 to 1 latches, respectively. Implementing the general case of 1-to-n conversion should be clear to one reasonably skilled in the art from the description of the specific case with n=4. A serial stream 60 is fed into the conversion circuit 50 to produce a parallel stream 66. The blocks of data in the parallel stream 66 correspond exactly to the bit blocks 62 that are processed by the converter 50. The converter 50 is nearly identical to the previous embodiment converter 40, and so items numbers for identical components have been kept the same, indicating identical functionality. The only difference is that the latch cascade 42d is not present in the converter 50, so that sampler 12d directly provides synchronized output Dₓ. Note that sampler 12d outputs data on the sampling edge of sampling clock signal CLK4, as does every final latch 44f in synchronization block 40a. Output data A, B, C and Dₓ is therefore synchronized, and is consistent with the arrangements of the sampled serial bit blocks 62. Hence, for the general 1-to-n serial-to-parallel conversion circuit, it is possible to have only n−1 latch cascades while still ensuring output data synchronization, and continuing to provide adequate setup and hold times for the latches 44.

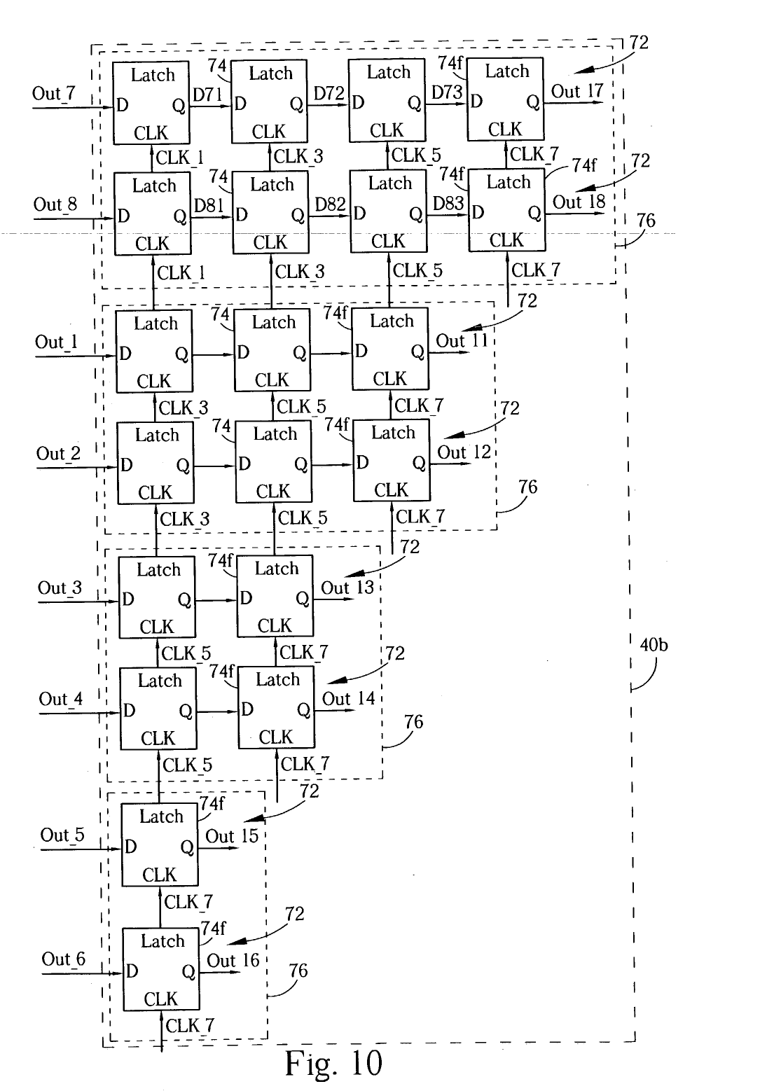

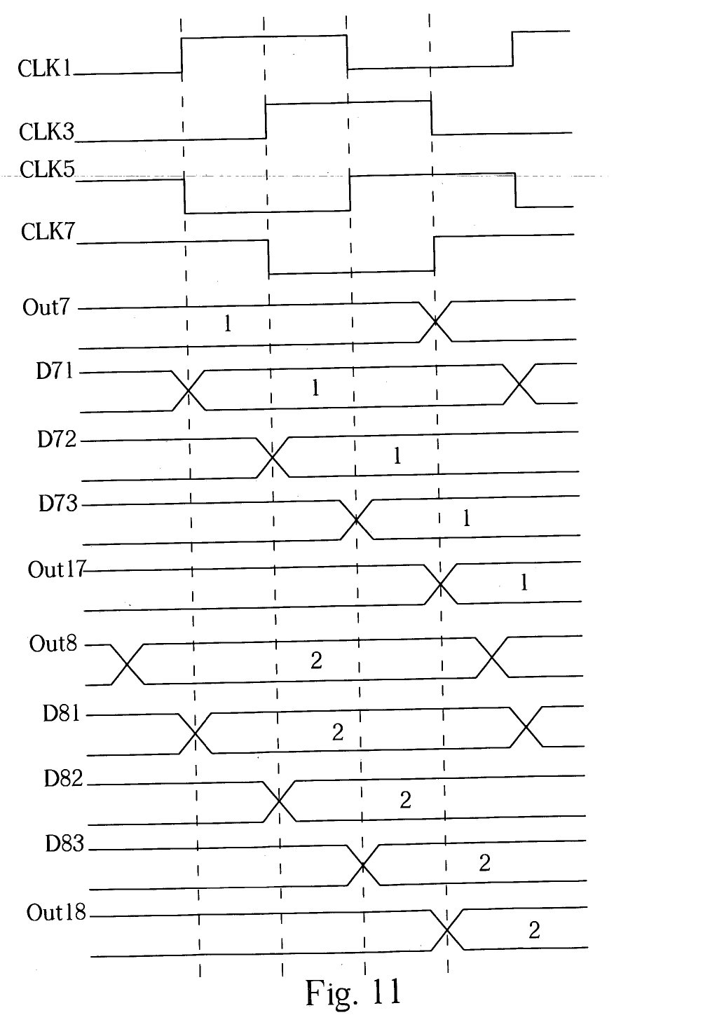

Finally, it should be noted that the general case 1-to-n sampling block 11 will utilize n sampling clocks CLK1-CLKn, generating n unsynchronized parallel outputs Out_1 to Out_n, respectively. However, the general case present invention synchronization block 40, 40a can actually utilize only m of the n sampling clocks to perform synchronization. An example of this is shown in FIG. 10 and FIG. 11. FIG. 10 is a block diagram of a second embodiment 8-bit synchronization block 40b according to the present invention. FIG. 11 is a timing diagram for the synchronization block 40b. The synchronization block 40b accepts as parallel inputs unsynchronized data on lines Out_1 to Out_8. This data is respectively generated by, and hence synchronized with, corresponding sampling clocks CLK_1 to CLK_8, respectively. The synchronization block 40b generates as output synchronized parallel data on lines Out11, Out12, Out13, . . . , Out18, respectively. Although the sampling block (not shown) utilizes eight sampling clocks CLK_1 to CLK_8, the synchronization block 40b makes use of only four of the sampling clocks to synchronize the data: CLK_1, CLK_3, CLK_5 and CLK_7. Hence, each latch cascade 72 has at most four latches 74. A final latch 74f in each latch cascade 72 is triggered by the same sampling clock CLK_7, and hence all final latches 74f are synchronized with each other. Furthermore, each latch 74 is provided ample setup and hold times, and so racing issues are completely avoided. This is clearly illustrated in FIG. 11, which shows the various intermediate signals associated with unsynchronized inputs Out_7 and Out_8 to generate synchronized outputs Out17 and Out18. Within the latch cascade 72 connected to input Out_7, these intermediate signals include D71, D72 and D73. A similar latch cascade 72 is connected to input Out_8, and has intermediate signals D81, D82 and D83. The general case for the synchronization block 40b is a synchronization block that performs synchronization for p×s unsynchronized bits. There is provided p×s latch cascades, which can be broken up into p cascade blocks, each cascade block having s identical latch cascades, and p synchronizing clocks are used so that each latch cascade has at most p latches. In the example of FIG. 10, there are 4×2 unsynchronized bits Out_1-Out_8, requiring 4×2 latch cascades 72 that are divided into 4 cascade blocks 76, each cascade block 76 having 2 identical latch cascades 72. Four synchronizing clocks CLK_1, CLK_3, CLK_S and CLK_7 are utilized. Note that the phase stepping between the clocks is “s”. That is, for p×s sampling clocks labeled in order of phase from CLK_1 to CLK_p×s, the synchronization clocks used in the general synchronization block 40b should be analogous to CLK_1, CLK_1+s, CLK_1 +2s, CLK_1+3s, etc.

In contrast to the prior art, the present invention provides latch cascades for the unsynchronized output data lines. Each latch cascade has at least a final latch, and all final latches are triggered by the same triggering clock signal. The latch which serves as the input latch of a latch cascade (and which could, in the special case, also be the final latch for the latch cascade) is triggered by a triggering signal that is phase shifted to occur after the sampling signal of the output data line connected to the input latch. This assures the input latch adequate sampling and hold times to accurately latch data on the unsynchronized output data line. Sampling data, as obtained from the unsynchronized output data lines, cascades through the latch cascades, and is ultimately synchronized by the final latches. The number of latches in each latch cascade is adjusted to provide adequate propagation delays to feed the sampled data into the final latch.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for synchronizing n output data lines, each output data line generating data according to a corresponding sampling clock, the method comprising:
providing a latch cascade for each of at least n−1 of the output data lines, each latch cascade having an input end, an output end, and at least one latch;
wherein data presented at the input end cascades through the latch cascade and is presented at the output end, the output end being a final latch in the latch cascade, and the output data line is connected to the input end of the latch cascade;
setting the final latch in each latch cascade to be triggered by a common clock signal; and
for each latch cascade having two or more latches, setting an initial latch in each latch cascade to be triggered by a triggering clock that is phase shifted after the sampling clock of the corresponding output data line, the corresponding output data line connected to the initial latch.

2. The method of claim 1 wherein the common clock is one of the sampling clocks.

3. The method of claim 1 further comprising providing each latch in each latch cascade with a corresponding trigger clock; wherein for each latch cascade, for any first latch feeding data to a subsequent second latch, the trigger clock for the second latch is phase shifted after the trigger clock for the first latch.

4. The method of claim 3 wherein each trigger clock is one of the sampling clocks.

5. The method of claim 4 wherein the trigger clock of the initial latch in each latch cascade having two or more latches is the sampling clock for a subsequent output data line of the corresponding output data line.

6. A circuit for performing the method of claim 1.

7. A one-to-n serial to parallel conversion circuit comprising:
a serial data input line for providing a stream of serial data;
n samplers for sampling the serial data input line, each sampler comprising an input port connected to the serial input line and an output port for providing associated output data from the stream of serial data;
n sample clock lines respectively connected to the n samplers for respectively triggering the n samplers to provide the associated output data; and
at least n−1 latch cascades, each latch cascade comprising an input end, an output end, and at least one latch; wherein data presented at the input end cascades through the latch cascade and is presented at the output end, the output end being a final latch in the latch cascade, at least n−1 output ports of the n samplers respectively connected to the at least n−1 input ends of the at least n−1 latch cascades;
wherein the final latch in each latch cascade is connected to a common trigger clock line, and other latches in each latch cascade are connected to respective trigger clock lines.

8. The circuit of claim 7 wherein the common trigger clock line is electrically connected to one of the n sample clocks lines.

9. The circuit of claim 8 wherein each trigger clock line is respectively electrically connected to one of the other n sample clock lines that are not electrically connected to the common trigger clock line.

10. The circuit of claim 7 wherein n=p×s, and the one-to-n serial to parallel conversion circuit comprises p cascade blocks, each cascade block having s latch cascades with the same number of latches.
